(19) United States
(12) Patent Application Publication
(10) Pub. No.: US 2014/0311776 A1
(43) Pub. Date: Oct. 23, 2014

(54) PLATING APPARATUS, PLATING METHOD, METHOD OF MANUFACTURING PRINTED CIRCUIT BOARD AND PRINTED CIRCUIT BOARD

(71) Applicant: NITTO DENKO CORPORATION, OSAKA (JP)

(72) Inventor: Hayato TAKAKURA, Ibaraki-shi, Osaka (JP)

(73) Assignee: NITTO DENKO CORPORATION, OSAKA (JP)

(21) Appl. No.: 14/230,505

(22) Filed: Mar. 31, 2014

(30) Foreign Application Priority Data
Apr. 19, 2013 (JP) 2013-088340

(51) Int. Cl. H05K 3/00; H05K 1/05

(52) U.S. Cl. CPC H05K 3/007; H05K 1/05
USPC 174/255; 204/242; 205/136; 205/125

(57) ABSTRACT

A voltage is applied between a stainless steel plate and an electrode such that the stainless steel plate is an anode, whereby a passive film formed at a portion to be plated of the stainless steel plate melts due to the reduction reaction and is removed. Thereafter, a voltage is applied between the stainless steel plate and the electrode such that the stainless steel plate is a cathode, whereby a plating underlayer is formed at the portion to be plated of the stainless steel plate from which the passive film is removed.

### BACKGROUND OF THE INVENTION

1. Field of the Invention

The present invention relates to a plating apparatus, a plating method, a method of manufacturing a printed circuit board and the printed circuit board.

2. Description of Related Art

A stainless steel is used for an electronic component, a circuit board and the like. In a case in which an external circuit is connected to the stainless steel, a plating layer made of nickel, gold, copper or the like is formed at the surface of the stainless steel.

A passive film is formed at the surface of the stainless steel. This passive film reduces adhesion of the plating layer. For example, in order to improve adhesion of the plating layer, an underlayer of the plating layer is formed at the surface of the stainless steel while the surface of the stainless steel is activated by strike plating. Thereafter, the plating layer made of a desired material is formed on the underlayer (see JP 2011-246739 A, for example).

### BRIEF SUMMARY OF THE INVENTION

When the strike plating is performed on the stainless steel, a chloride bath is generally used as an electrolyte bath. However, because the chloride bath is highly corrosive, corrosion such as pitting corrosion is likely to occur at the stainless steel.

An object of the present invention is to provide a plating apparatus, a plating method, a method of manufacturing a printed circuit board and the printed circuit board in which a plating layer having high adhesion can be formed at a surface of a member to be plated that includes a stainless steel while corrosion of the member to be plated is prevented.

(1) According to one aspect of the present invention, a plating apparatus for forming a plating layer at a surface of a member to be plated that includes a stainless steel includes a plating tank that stores an electrolytic solution, a first electrode provided in the plating tank, a second electrode provided in the plating tank, a first voltage applier that applies a voltage between the member to be plated and the first electrode such that the member to be plated is an anode, and a second voltage applier that applies a voltage between the member to be plated and the second electrode such that the member to be plated is a cathode, wherein the plating layer is formed at a predetermined portion to be plated by application of a voltage by the second voltage applier after a passive film is removed from the portion to be plated of the member to be plated by application of a voltage by the first voltage applier.

In the plating apparatus, the electrolytic solution is stored in the plating tank, and the first and second electrodes are provided in the electrolytic solution. The portion to be plated at which the plating layer is to be formed is provided at the member to be plated that includes a stainless steel. A voltage is applied between the member to be plated and the first electrode by the first voltage applier such that the member to be plated is an anode in the plating tank. Thus, a passive film is removed from the portion to be plated of the member to be plated due to reduction. Subsequently, a voltage is applied between the member to be plated and the second electrode by the second voltage applier such that the member to be plated is a cathode in the plating tank. Thus, the plating layer made of the component in the electrolytic solution is formed at the portion to be plated of the member to be plated.

In this case, because the plating layer is formed at the portion to be plated of the member to be plated after the passive film is removed from the portion to be plated, adhesion of the plating layer is improved. Further, even if the electrolytic solution having low corrosiveness is used, the passive film can be removed by the voltage application that makes the member to be plated an anode. Therefore, corrosion of the member to be plated can be prevented.

(2) The first and second electrodes may be integrated or separated, and the first and second voltage appliers may be integrated or separated. If the first and second electrodes are integrated and the first and second voltage appliers are integrated, the size of the plating apparatus can be reduced. On the other hand, if the first and second electrodes are separated and the first and second voltage appliers are separated, the control of the voltage application becomes easy.

(3) The first and second electrodes may be separated, the first electrode may be arranged in a first region in the plating tank, the second electrode may be arranged in a second region in the plating tank, and the plating apparatus further includes a transporter that transports the member to be plated such that the member to be plated sequentially pass through first and second regions in the plating tank.

In this case, the member to be plated is transported by the transporter such that the portion to be plated is positioned in the first region, and a voltage is applied between the member to be plated and the first electrode in that state. Subsequently, the member to be plated is transported by the transporter such that the portion to be plated is positioned in the second region, and a voltage is applied between the member to be plated and the second electrode in that state. Thus, the removal of the passive film from and the formation of the plating layer at the portion to be plated can be efficiently sequentially performed.

(4) The electrolytic solution stored in the plating tank may include a sulfuric acid chemical solution, and a pH of the electrolytic solution may be less than 2.0.

In this case, the passive film on the portion to be plated can be well removed while corrosion of the member to be plated is prevented.

(5) The plating apparatus may further include a third electrode provided in the plating tank, and a third voltage applier that applies a voltage between the member to be plated and the third electrode such that the member to be plated is a cathode, wherein the member to be plated may have a first member made of a stainless steel and a second member made of a conductive material other than a stainless steel, and the portion to be plated may be provided at each of the first and second members, and the first and second electrodes may be arranged to be opposite to the first member of the member to be plated, and the third electrode may be arranged to be opposite to the second member of the member to be plated.

In this case, the passive film is formed at the surface of the first member that is made of a stainless steel, and the passive film is difficult to be formed at the surface of the second member made of a conductive material other than a stainless steel. The removal of the passive film and the formation of the plating layer are sequentially performed on the portion to be plated of the first member, and only the formation of the plating layer is performed on the portion to be plated of the second member. Thus, in the common plating tank, the plating layer can be well formed at each of the portion to be plated of the first member made of a stainless steel and the portion to be plated of the second member made of another conductive material.

(6) According to another aspect of the present invention, a plating method for forming a plating layer at a surface of a member to be plated that includes a stainless steel includes the steps of removing a passive film from a predetermined portion to be plated of the member to be plated by applying a voltage between the member to be plated and an electrode in a plating tank that stores an electrolytic solution such that the member to be plated is an anode, and forming the plating layer at the portion to be plated of the member to be plated by applying a voltage between the member to be plated and an electrode in the plating tank such that the member to be plated is a cathode.

In the plating method, a voltage is applied between the member to be plated and the electrode such that the member to be plated is an anode in the plating tank in which the electrolytic solution is stored. Thus, the passive film is removed due to reduction from the portion to be plated of the member to be plated. Subsequently, a voltage is applied between the member to be plated and the electrode such that the member to be plated is a cathode in the plating tank. Thus, the plating layer made of the component in the electrolytic solution is formed at the portion to be plated of the member to be plated.

In this case, because the plating layer is formed at the portion to be plated of the member to be plated after the passive film is removed from the portion to be plated, adhesion of the plating layer is improved. Further, even if the low corrosive electrolytic solution is used, the passive film can be removed by the voltage application that makes the member to be plated an anode. Therefore, corrosion of the member to be plated can be prevented.

(7) The member to be plated may have a first member made of a stainless steel and a second member made of a conductive material other than a stainless steel, and the portion to be plated may be provided at each of the first and second members, the step of removing the passive film may include the step of removing the passive film from the portion to be plated of the first member of the member to be plated, and the step of forming the plating layer may include the step of forming the plating layer at a portion to be plated of the first member of the member to be plated, and the step of forming the plating layer at a portion to be plated of the second member of the member to be plated.

In this case, the passive film is formed at the surface of the first member made of a stainless steel, and the passive film is difficult to be formed at the surface of the second member made of a conductive material other than a stainless steel. The removal of the passive film and the formation of the plating layer are sequentially performed on the portion to be plated of the first member, and only the formation of the plating layer is performed on the portion to be plated of the second member. Thus, in the common plating tank, the plating layer can be well formed at each of the portion to be plated of the first member made of a stainless steel, and the portion to be plated of the second member made of another conductive material.

(8) The step of forming the plating layer may include the step of forming the plating layer at the portion to be plated of the second member of the member to be plated while forming the plating layer at the portion to be plated of the first member of the member to be plated.

In this case, the plating layer can be efficiently formed at each of the portion to be plated of the first member and the portion to be plated of the second member.

(9) According to yet another aspect of the present invention, a method of manufacturing a printed circuit board includes the steps of forming a base insulating layer on a support substrate made of a stainless steel as a member to be plated, forming a first wiring trace on the base insulating layer to be electrically connected to one portion of the support substrate, forming a first terminal portion as a portion to be plated made of the one portion by removing a surrounding portion of the one portion of the support substrate such that the one portion of the support substrate is separated from another portion, and forming a plating layer at the first terminal portion of the support substrate by the above-mentioned plating method.

According to the method of manufacturing, the first wiring trace is formed on the base insulating layer to be electrically connected to one portion of the support substrate after the base insulating layer is formed on the support substrate made of a stainless steel. Subsequently, the surrounding portion of the one portion of the support substrate is removed such that the one portion of the support substrate is separated from the remaining portion, whereby the first terminal portion made of one portion of the support substrate is formed. Thereafter, the plating layer is formed at the first terminal portion by the above-mentioned plating method.

In this case, because the above-mentioned plating method is used, adhesion of the plating layer is improved, and corrosion of the support member and the first wiring trace can be prevented.

(10) The method of manufacturing the printed circuit board may further include the step of forming a second wiring trace as the member to be plated on the base insulating layer, wherein the support substrate may constitute the first member of the member to be plated, and the second wiring trace may constitute the second member of the member to be plated, the second wiring trace may include a second terminal portion as the portion to be plated, and the step of forming the plating layer may include the step of forming the plating layer at the first terminal portion of the support substrate and the second terminal portion of the second wiring trace by the above-mentioned plating method.

In this case, in the common plating tank, the plating layer can be well formed at each of the first terminal portion of the support member made of a stainless steel and the second terminal portion of the second wiring trace made of a conductive material other than a stainless steel.

(11) According to yet another aspect of the present invention, a printed circuit board is manufactured by the above-mentioned method of manufacturing.

In the printed circuit board, because the plating layer is formed by the above-mentioned plating method, adhesion of the plating layer to the first terminal portion is improved, and corrosion of the support member and the first wiring trace can be prevented.

The present invention enables the plating layer having high adhesion to be formed at the surface of the member to be plated while corrosion of the member to be plated is prevented.

Other features, elements, characteristics, and advantages of the present invention will become more apparent from the following description of preferred embodiments of the present invention with reference to the attached drawings.

### BRIEF DESCRIPTION OF THE SEVERAL VIEWS OF THE DRAWING

FIG. 1 is a schematic diagram showing the configuration of a plating apparatus according to embodiments of the present invention;

FIG. 2 is a schematic diagram showing a modified example of the plating apparatus of FIG. 1;

FIG. 3 is a plan view of a suspension board;

FIG. 4 is a cross sectional view taken along the line A-A of FIG. 3;

FIG. 5 is an enlarged plan view of a tongue viewed in one direction;

FIG. 6 is an enlarged plan view of the tongue viewed in another direction;

FIG. 7 is a cross sectional view taken along the line B-B of FIGS. 5 and 6;

FIG. 8 is a cross sectional view taken along the line C-C of FIGS. 5 and 6;

FIGS. 9(a) and 9(b) are sectional views for explaining the steps of a method of manufacturing the suspension board;

FIGS. 10(a) and 10(b) are sectional views for explaining the steps of the method of manufacturing the suspension board;

FIGS. 11(a) and 11(b) are sectional views for explaining the steps of the method of manufacturing the suspension board;

FIGS. 12(a) and 12(b) are sectional views for explaining the steps of the method of manufacturing the suspension board;

FIGS. 13(a) and 13(b) are sectional views for explaining the steps of the method of manufacturing the suspension board;

FIGS. 14(a) and 14(b) are sectional views for explaining the steps of the method of manufacturing the suspension board;

FIGS. 15(a) and 15(b) are sectional views for explaining the steps of the method of manufacturing the suspension board;

FIGS. 16(a) and 16(b) are sectional views for explaining the steps of the method of manufacturing the suspension board; and

FIGS. 17(a) and 17(b) are sectional views for explaining the steps of the method of manufacturing the suspension board.

### DESCRIPTION OF THE PREFERRED EMBODIMENTS

A plating apparatus, a plating method, a method of manufacturing a printed circuit board and the printed circuit board according to embodiments of the present invention will be described below with reference to drawings.

### (1) Plating Apparatus

### (1-1) Configuration

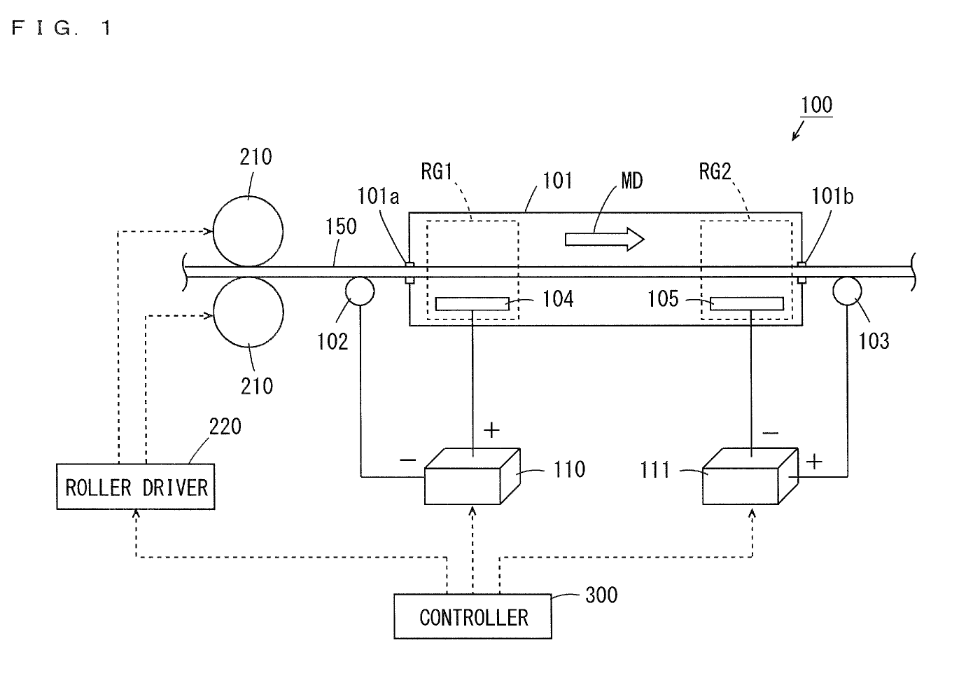

FIG. 1 is a schematic diagram showing the configuration of the plating apparatus according to the embodiments of the present invention. In the plating apparatus of FIG. 1, a plating underlayer is formed at the surface of a member to be plated made of a stainless steel (SUS 304, for example).

As shown in FIG. 1, the plating apparatus 100 includes a plating tank 101, power feed rollers 102, 103, electrodes 104, 105, rectifiers 110, 111, a pair of transport rollers 210, a roller driver 220 and a controller 300. The rectifiers 110, 111 and the roller driver 220 are controlled by the controller 300.

In the plating tank 101, an electrolytic solution is stored. As an acid component of the electrolytic solution, sulfuric acid, nitric acid, sulphamic acid, hydrochloric acid or the like is used, for example. A highly corrosive component such as chlorine is preferably not included in the electrolytic solution. Even if a highly corrosive component is included, its concentration is preferably low. In order to prevent corrosion of the member to be plated, a sulfuric acid chemical solution is preferably used as the electrolytic solution. The electrolytic solution may include an ion component of a metallic material (nickel in the present example) that is to be formed as the plating underlayer.

In the present embodiment, the electrolytic solution includes nickel sulphate as a sulfuric acid chemical solution. In this case, the pH (the hydrogen ion exponent) of the electrolytic solution is preferably less than 2.0. The pH of the electrolytic solution is less than 2.0, whereby a passive film at the surface of the member to be plated can evenly melt, and the occurrence of pitting corrosion can be prevented. Further, the pH of the electrolytic solution is preferably not less than 0.

The concentration of nickel sulphate in the electrolytic solution is preferably not less than 100 g/L and less than 400 g/L, and is more preferably not less than 150 g/L and less than 300 g/L. The nickel sulphate concentration is not less than 100 g/L, so that nickel can be efficiently deposited at the surface of the member to be plated. Further, the concentration of nickel sulphate is less than 400 g/L, so that the concentration of nickel sulphate is prevented from exceeding the solubility. Further, an increase in cost is inhibited.

The concentration of sulfuric acid in the electrolytic solution is preferably not less than 15 g/L and less than 100 g/L, and is more preferably not less than 25 g/L and less than 60 g/L. The sulfuric acid concentration is not less than 15 g/L, so that the pH of the electrolytic solution is easily adjusted to an appropriate range (less than 2.0). Further, the sulfuric acid concentration is less than 100 g/L, so that a decrease in the deposition efficiency of nickel can be prevented.

In the present embodiment, the member to be plated is a long-sized plate-shaped member (hereinafter referred to as a stainless steel plate) 150 made of a stainless steel. The stainless steel plate 150 is held by the pair of transport rollers 210 therebetween. The pair of transport rollers 210 is driven to be rotated by the roller driver 220, so that the stainless steel plate 150 is transported. An inlet port 101a and an outlet port 101b are provided at the plating tank 101. The stainless steel plate 150 is carried into the plating tank 101 through the inlet port 101a, and is carried out from the plating tank 101 through the outlet port 101b. In this case, in the plating tank 101, the stainless steel plate 150 is transported in the direction of the arrow MD (hereinafter referred to as a transport direction MD) in the electrolytic solution. Thus, the plating apparatus 100 performs electroplating on the stainless steel plate 150 using a roll-to-roll system.

The power feed rollers 102, 103 are arranged outside of the plating tank 101. The power feed roller 102 is arranged to come into contact with a portion of the stainless steel plate 150 at an upstream position with respect to the inlet port 101a. The power feed roller 103 is arranged to come into contact with a portion of the stainless steel plate 150 at a downstream position with respect to the outlet port 101b. The power feed rollers 102, 103 are provided to be rotatable such that friction does not occur between the power feed rollers 102, 103 and the stainless steel plate 150. Further, the power feed rollers 102, 103 may be driven to be rotated by a motor or the like such that the force in the transport direction MD is exerted on the stainless steel plate 150 from the power feed rollers 102, 103.

A first region RG1 and a second region RG2 are provided in the plating tank 101. In the transport direction MD of the stainless steel plate 150, the first region RG1 is arranged at an upstream position with respect to the second region RG2. In the first region RG1, the electrode 104 is arranged to be opposite to one surface of the stainless steel plate 150, and in the second region RG2, the electrode 105 is arranged to be opposite to the one surface of the stainless steel plate 150. A plurality of portions on which the plating underlayers are to be formed (hereinafter referred to as a portion to be plated) are provided at the one surface of the stainless steel plate 150. As a material for the electrode 104, a stainless steel, nickel, platinum or the like is used, for example. As a material for the electrode 105, nickel, a nickel alloy, platinum or the like is used, for example.

The power feed roller 102 is connected to the negative electrode of the rectifier 110, and the electrode 104 is connected to the positive electrode of the rectifier 110. The power feed roller 103 is connected to the positive electrode of the rectifier 111, and the electrode 105 is connected to the negative electrode of the rectifier 111. A voltage is applied between the stainless steel plate 150 that comes into contact with the power feed roller 102, and the electrode 104 by the rectifier 110. In this case, the stainless steel plate 150 is an anode, and the electrode 104 is a cathode. Further, a voltage is applied between the stainless steel plate 150 that comes into contact with the power feed roller 103, and the electrode 105 by the rectifier 111. In this case, the stainless steel plate 150 is a cathode, and the electrode 105 is an anode.

The current density in the electrolytic solution applied by the rectifier 110 (the current density between the electrode 104 and the stainless steel plate 150) is preferably not less than 0.5 A/dm² and less than 5 A/dm², and is more preferably not less than 1 A/dm² and less than 3 A/dm². The current density in the electrolytic solution applied by the rectifier 110 is not less than 0.5 A/dm², so that the passive film at the surface of the stainless steel plate 150 can be efficiently removed in a short period of time. Further, the current density in the electrolytic solution applied by the rectifier 110 is less than 5 A/dm², so that the stainless steel plate 150 can be prevented from excessively melting.

The current density (the current density between the electrode 105 and the stainless steel plate 150) in the electrolyte solution applied by the rectifier 111 is preferably not less than 1 A/dm² and less than 100 A/dm². The current density in the electrolyte solution applied by the rectifier 111 is not less than 1 A/dm², so that nickel can be efficiently deposited on the surface of the stainless steel plate 150. Further, the current density in the electrolyte solution applied by the rectifier 111 is less than 100 A/dm², so that an applied voltage between the stainless steel plate 150 that has high electrical resistance and the electrode 105 is prevented from excessively increasing.

### (1-2) Formation of Plating Underlayer

A formation method of the plating under layer at the stainless steel plate 150 in the plating apparatus 100 of FIG. 1 will be described. The roller driver 220 and the rectifiers 110, 111 are controlled by the controller 300, whereby the operation of the below-mentioned plating apparatus 100 is realized.

The stainless steel plate 150 is carried into the plating tank 101 through the inlet port 101a by the transport rollers 210, and is transported in the transport direction MD. When at least one portion to be plated of the stainless steel plate 150 is positioned in the first region RG1, a voltage is applied between the stainless steel plate 150 and the electrode 104 by the rectifier 110. In this case, because the stainless steel plate 150 is an anode, the passive film formed at the portion to be plated of the stainless steel plate 150 melts due to the reduction reaction, and is removed. Hereinafter, such a removal process of the passive film is referred to as a reverse electrolytic process.

Subsequently, when the portion to be plated after the reverse electrolytic process is positioned in the second region RG2, a voltage is applied between the stainless steel plate 150 and the electrode 105 by the rectifier 111. In this case, nickel is deposited on the portion to be plated (hereinafter referred to as a film removal portion) of the stainless steel plate 150 from which the passive film is removed. Thus, the plating underlayer made of nickel is formed at the film removal portion of the stainless steel plate 150. Hereinafter, such a formation process of the plating underlayer is referred to as an electrolytic plating process. The plating underlayer has a thickness of not less than 0.01 μm and not more than 1.0 μm, for example, and preferably has a thickness of not less than 0.03 μm and not more than 0.1 μm.

Similarly, when the unprocessed portion to be plated is positioned in the first region RG1, the reverse electrolytic process is performed, and when the film removal portion is positioned in the second region RG2, the electrolytic plating process is performed.

The reverse electrolytic process is performed with the portion to be plated being located at a position (in the first region RG1) opposite to the electrode 104, whereby the removal efficiency of the passive film at the portion to be plated is increased. Similarly, the electrolytic plating process is performed with the film removal portion being located at a position (in the second region RG2) opposite to the electrode 105, whereby the deposition efficiency of plating in the film removal portion is increased.

In this manner, after the plating underlayer is formed at the portion to be plated of the stainless steel plate 150, a plating layer (hereinafter referred to as a main plating layer) made of a desired material is formed on the plating underlayer by electroplating in another plating tank (not shown). The main plating layer has a thickness of not less than 0.1 μm and not more than 5.0 μm, for example, and preferably has a thickness of not less than 0.3 μm and not more than 3.0 μm. As a material for the main plating layer, gold (Au), nickel (Ni), copper (Cu), zinc (Zn), chrome (Cr) or the like is used, for example.

While the reverse electrolytic process and the electrolytic plating process are sequentially performed while the transportation of the stainless steel plate 150 is continued in the above-mentioned example, the transportation of the stainless steel plate 150 may be temporarily stopped as necessary. For example, when the portion to be plated reaches the first region RG1, the transportation of the stainless steel plate 150 may be temporarily stopped, and the reverse electrolytic process may be performed in that state. Further, when the film removal portion reaches the second region RG2, the transportation of the stainless steel plate 150 may be temporarily stopped, and the electrolytic plating process may be performed in that state.

Further, in a case in which one portion to be plated before the reverse electrolytic process and another portion to be plated after the reverse electrolytic process and before the electrolytic plating process are not electrically connected, the electrolytic plating process may be performed on another portion to be plated in the second region RG2 simultaneously as the reverse electrolytic process is performed on the one portion to be plated in the first region RG1.

Further, if the reverse electrolytic process and the electrolytic plating process can be appropriately performed, the integrally provided common electrode may be used instead of the separately provided electrodes 104, 105, and the integrally provided common rectifier may be used instead of the separately provided rectifiers 110, 111. In this case, a voltage is applied between the member to be plated and the common electrode such that the member to be plated is a cathode after a voltage is applied between the member to be plated and the common electrode by the common rectifier such that the member to be plated is an anode. Thus, the reverse electrolytic process and the electrolytic plating process can be performed on the portion to be plated while a decrease in size of the plating apparatus 100 is realized.

### (1-3) Effects

In the above-mentioned plating apparatus 100, the plating underlayer is formed on the portion to be plated by the electrolytic plating process after the passive film is removed from the portion to be plated of the stainless steel plate 150 by the reverse electrolytic process. Thus, adhesion of the plating underlayer is improved. Further, because it is possible to remove the passive film by the reverse electrolytic process without using the electrolytic solution including a highly corrosive component such as chlorine, corrosion of the stainless steel plate 150 can be prevented.

### (1-4) Modified Example

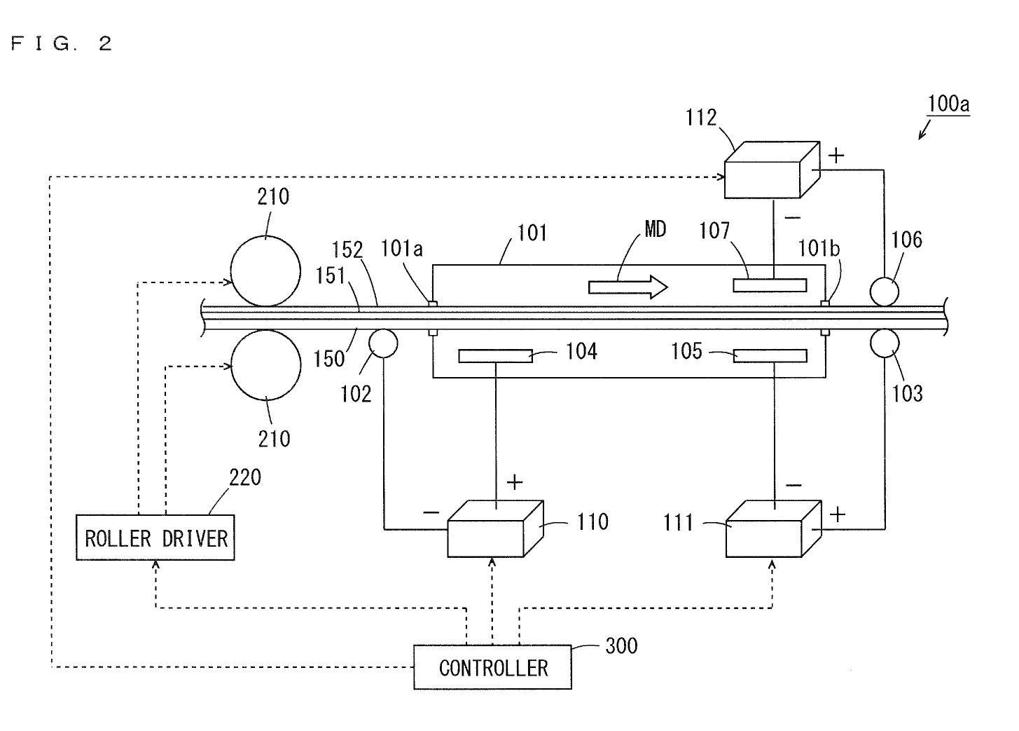

FIG. 2 is a schematic diagram showing the modified example of the plating apparatus 100 of FIG. 1. Regarding a plating apparatus 100a of FIG. 2, difference from the plating apparatus 100 of FIG. 1 will be described.

In the present example, a conductor layer 152 made of copper, for example, is formed at another surface of a stainless steel plate 150 via an insulating layer 151. In this case, the stainless steel plate 150 and the conductor layer 152 correspond to a member to be plated. The conductor layer 152 has a plurality of portions (portions to be plated) at which plating underlayers are to be formed.

The plating apparatus 100a of FIG. 2 further includes a power feed roller 106, an electrode 107 and a rectifier 112. The power feed roller 106 is arranged to come into contact with a portion of the conductor layer 152 at a downstream position with respect to an outlet port 101b.

The electrode 107 is arranged at a position (the second region RG2 of FIG. 1) opposite to an electrode 105 with the stainless steel plate 150, the insulating layer 151 and the conductor layer 152 sandwiched therebetween. In this case, the electrode 107 is opposite to the conductor layer 152. As a material for the electrode 107, nickel, a nickel alloy, platinum or the like is used, for example.

The power feed roller 106 is connected to the positive electrode of the rectifier 112, and the electrode 107 is connected to the negative electrode of the rectifier 112. A voltage is applied between the stainless steel plate 150 and the electrode 105 by the rectifier 111, and a voltage is applied between the conductor layer 152 and the electrode 107 by the rectifier 112. Thus, the electrolytic plating process is simultaneously performed on the portion to be plated (a film removal portion) of the stainless steel plate 150 and the portion to be plated of the conductor layer 152.

Because a passive film is difficult to be formed at the surface of the conductor layer 152, it is not necessary to perform a reverse electrolytic process on the conductor layer 152 in the present example. When the passive film is formed at the surface of the conductor layer 152, another electrode and another rectifier may be provided such that the reverse electrolytic process is performed on the conductor layer 152.

Further, while the power feed roller 106 and the electrode 107 are connected to the rectifier 112 separately provided from the rectifier 111 in the example of FIG. 2, the invention is not limited to this. If a voltage can be appropriately applied between the conductor layer 152 and the electrode 107, the power feed roller 106 and the electrode 107 may be connected to the rectifier 111.

Further, in a case in which the stainless steel plate 150 and the conductor layer 152 are electrically connected through a via or the like, because it is not necessary to individually supply electricity to the stainless steel plate 150 and the conductor layer 152, only one of the power feed rollers 103, 106 may be provided.

### (1-5) Inventive Examples and Comparative Examples

In the above-mentioned plating apparatuses 100, 100a, a plating underlayer was formed at the member to be plated under various conditions, and was evaluated.

### (1-5-1) Inventive Example 1

The stainless steel plate 150 that is made of SUS 304 and has a thickness of 18 μm was used as the member to be plated. A degreasing process of the surface of the stainless steel plate 150 was performed using a degreasing liquid for 2 minutes, and the stainless steel plate 150 after the degreasing process was sufficiently washed with water. Thereafter, in the plating apparatus 100 of FIG. 1, the reverse electrolytic process and the electrolytic plating process were sequentially performed on one portion to be plated.

An aqueous solution including nickel sulphate was used as the electrolytic solution. The pH of the electrolytic solution was set to 0, the concentration of the nickel sulphate in the electrolytic solution was set to 200 g/L and the concentration of sulfuric acid was set to 40 g/L. Further, the temperature of the electrolytic solution was set to 30° C. Further, the current density in the electrolytic solution applied by the rectifier 110 was set to 1.0 A/dm², and the current density in the electrolytic solution applied by the rectifier 111 was set to 3.0 A/dm². A time period for the reverse electrolytic process was set to 1 minute, and a time period for the electrolytic plating process was set to 3.5 minutes.

### (1-5-2) Inventive Example 2

The reverse electrolytic process and the electrolytic plating process were performed similarly to the above-mentioned inventive example 1 except that the pH of the electrolytic solution in the plating tank 101 was set to 1.0, and a time period for the electrolytic plating process was set to 1 minute.

### (1-5-3) Inventive Example 3

The reverse electrolytic process and the electrolytic plating process were performed similarly to the above-mentioned inventive example 1 except that the pH of the electrolytic solution in the plating tank 101 was set to 4.0, and a time period for the electrolytic plating process was set to 1 minute.

### (1-5-4) Inventive Example 4

The stainless steel plate 150 and the conductor layer 152 of FIG. 2 were used as the member to be plated. The stainless steel plate 150 is made of SUS 304, and has a thickness of 18 μm. The conductor layer 152 is made of copper and has a thickness of 10 μm. The degreasing process of the stainless steel plate 150 and the conductor layer 152 was performed for 2 minutes using a degreasing solution, and the stainless steel plate 150 and the conductor layer 152 after the degreasing process were sufficiently washed with water. Thereafter, in the plating apparatus 100a of FIG. 2, the reverse electrolytic process and the electrolytic plating process were performed on one portion to be plated of the stainless steel plate 150, and the electrolytic plating process was performed on one portion to be plated of the conductor layer 152.

The composition and the temperature of the electrolytic solution is the same as the inventive example 2. The current density in the electrolytic solution applied by the rectifiers 110, 111 was the same as the inventive example 1. Further, the current density applied by the rectifier 112 was set to 3.0 A/dm². Similarly to the inventive examples 1 to 3, a time period for the reverse electrolytic process on the stainless steel plate 150 was set to 1 minute. Further, the electrolytic plating process was simultaneously performed on the stainless steel plate 150 and the conductor layer 152 for 1 minute.

### (1-5-5) Comparative Example 1

The electrolytic plating process was performed on the stainless steel plate 150 under a similar condition as the inventive example 3 without the reverse electrolytic process.

### (1-5-6) Comparative Example 2

The electrolytic process was performed on the stainless steel plate 150 under a similar condition as the comparative example 1 except for the following points.

An aqueous solution including nickel chloride was used instead of nickel sulphate. The pH of the electrolytic solution was set to 1, the concentration of the nickel chloride in the electrolytic solution was set to 240 g/L, the concentration of hydrochloric acid was set to 125 m/L. Further, the temperature of the electrolytic solution was set to 25° C. Further, the current density in the electrolytic solution applied by the rectifier 111 was set to 6 A/dm², and a time period for the electrolytic plating process was set to 2 minutes.

### (1-5-7) Evaluation

The thicknesses of the plating underlayers formed in the inventive examples 1 to 4, the comparative examples 1 and 2 were measured, and the plating efficiency was calculated based on the measured thicknesses. The plating efficiency refers to the ratio of the amount of the electricity actually consumed for the deposition of nickel with respect to the amount of electricity supplied to the member to be plated.

Further, a tape stripping experiment was performed on the plating underlayers formed in the inventive examples 1 to 4, and the comparative example 1 and 2. Specifically, a cellophane tape was attached to the member to be plated using finger pressure to adhere to the plating under layer, and the cellophane tape was stripped from the member to be plated using substantially constant force.

Further, absence and presence of corrosion of the member to be plated in the inventive examples 1 to 4, and the comparative examples 1 and 2 were found.

In Tables 1 and 2, the type of the electrolytic solution, the pH of the electrolytic solution, the absence and presence of the reverse electrolytic process, the material for the member to be plated, the thickness of the plating underlayer, the plating efficiency, the result of the tape stripping experiment and the absence and presence of corrosion of the member to be plated in the inventive examples 1 to 4, and the comparative examples 1 and 2 are shown.

TABLE 1

| | INVENTIVE | INVENTIVE | INVENTIVE |
|---|---|---|---|
| | EXAMPLE 1 | EXAMPLE 2 | EXAMPLE 3 |
| ELECTROLYTIC SOLUTION | SULFURIC ACID | SULFURIC ACID | SULFURIC ACID |
| | Ni | Ni | Ni |
| pH | 0 | 1 | 4 |
| REVERSE ELECTROLYTIC | YES | YES | YES |
| PROCESS | | | |
| MEMBER TO BE PLATED | SUS 304 | SUS 304 | SUS 304 |
| THICKNESS OF PLATING | ABOUT 0.15 | ABOUT 0.15 | ABOUT 1 |
| UNDERLAYER (μm) | | | |
| PLATING EFFICIENCY (%) | ABOUT 5 | ABOUT 30 | ABOUT 95 |
| TAPE STRIPPING EXPERIMENT | ∘ | ∘ | Δ |
| PRESENCE/ABSENCE OF | ∘ | ∘ | Δ |
| CORROSION | | | |

TABLE 2

| | INVENTIVE | COMPARATIVE | COMPARATIVE |
|---|---|---|---|
| | EXAMPLE 4 | EXAMPLE 1 | EXAMPLE 2 |
| ELECTROLYTIC SOLUTION | SULFURIC ACID | SULFURIC ACID | CHLORIDE Ni |
| | Ni | Ni | |
| pH | 1 | 4 | 1 |
| REVERSE ELECTROLYTIC | YES | NO | NO |
| PROCESS | | | |
| MEMBER TO BE PLATED | SUS 304 Cu | SUS 304 | SUS 304 |
| THICKNESS OF PLATING | ABOUT 0.15 | ABOUT 1 | ABOUT 0.5 |
| UNDERLAYER (μm) | | | |
| PLATING EFFICIENCY (%) | ABOUT 30 | ABOUT 95 | ABOUT 15 |
| TAPE STRIPPING EXPERIMENT | ∘ | x | ∘ |
| PRESENCE/ABSENCE OF | ∘ | ∘ | x |
| CORROSION | | | |

As shown in Tables 1 and 2, the plating underlayers were hardly stripped from the stainless steel plates 150 in the inventive examples 1, 2 and 4, and the comparative example 2 as a result of the tape stripping experiment. Further, in the inventive example 4, the plating underlayer was hardly stripped from the conductor layer 152 either. In the inventive example 3, part of the plating underlayer was stripped from the stainless steel plate 150. In the comparative example 1, the substantially entire plating underlayer was stripped from the stainless steel plate 150.

Further, in the inventive examples 1, 2 and 4, and the comparative example 1, corrosion of the stainless steel plates 150 did not occur. Further, in the inventive example 4, corrosion did not occur at the conductor layer 152 either. In the inventive example 3, corrosion occurred at part of the stainless steel plate 150. In the comparative example 2, corrosion occurred in a wide range of the stainless steel plate 150.

Accordingly, it was found that the reverse electrolytic process is performed before the electrolytic plating process, whereby the plating underlayer having high adhesion is formed at the surface of the stainless steel plate 150. Further, it was found that sulfuric acid is used as an acid component of the electrolytic solution, whereby corrosion of the stainless steel plate 150 is prevented.

On the other hand, when hydrochloric acid is used as the acid component of the electrolytic solution, even if the reverse electrolytic process is not performed, the plating underlayer having high adhesion was formed at the surface of the stainless steel plate 150. In this case, however, it was found that corrosion easily occurs at the stainless steel plate 150.

Further, the plating efficiency in the inventive examples 2 and 4 was higher than the plating efficiency in the inventive example 1, and the plating efficiency in the inventive example 3 was higher than the plating efficiency in the inventive examples 2 and 4. However, in the inventive examples 1, 2 and 4, it was possible to form the plating underlayer having a necessary thickness (0.15 μm) in a short period of time (1 to 3 minutes) without generating corrosion at the stainless steel plate 150. On the other hand, in the inventive example 3, corrosion occurred at part of the stainless steel plate 150 as described above. Accordingly, it was found that the pH is preferably less than 2 in a case in which the electrolytic solution includes nickel sulphate.

### (2) Printed Circuit Board

The printed circuit board and a method of manufacturing the printed circuit board according to embodiments of the present invention will be described. The printed circuit board in the below-mentioned embodiment is a suspension board with a circuit (hereinafter abbreviated as a suspension board) used in an actuator of a hard disc drive.

### (2-1) Configuration of Suspension Board

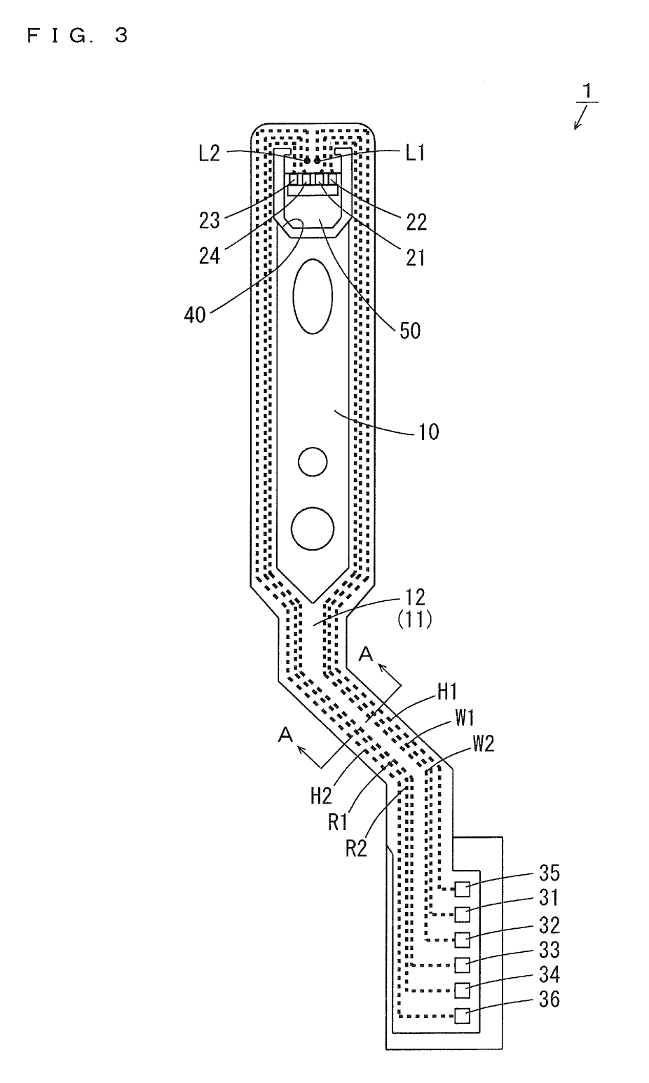

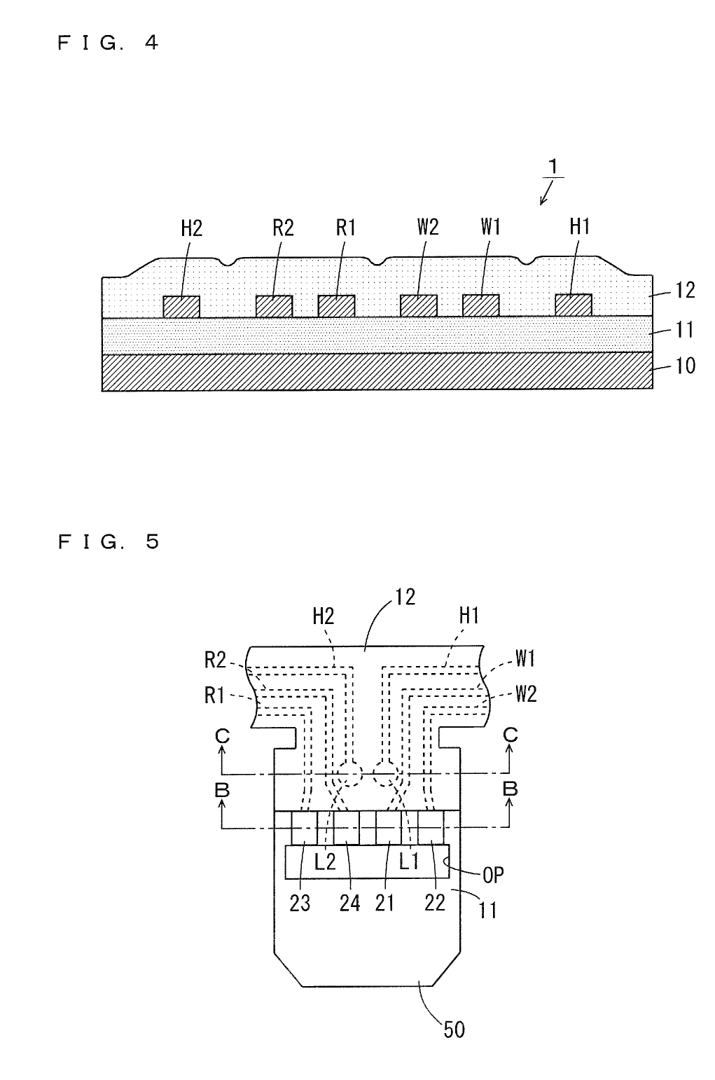

FIG. 3 is a plan view of the suspension board. FIG. 4 is a cross sectional view taken along the line A-A of FIG. 3. As shown in FIGS. 3 and 4, the suspension board 1 includes a long-sized support substrate 10. The support substrate 10 is made of a stainless steel (SUS).

A base insulating layer 11 made of polyimide, for example, is formed on the support substrate 10. Write wiring traces W1, W2, read wiring traces R1, R2 and heat-assisted wiring traces H1, H2 are formed on the base insulating layer 11. The write wiring traces W1, W2, the read wiring traces R1, R2 and the heat-assisted wiring traces H1, H2 are made of copper (Cu), for example.

The write wiring traces W1, W2, and the heat-assisted wiring trace H1 are formed in a region that extends along one lateral side of the support substrate 10. The heat-assisted wiring trace H1 is arranged outside of the write wiring traces W1, W2. The read wiring traces R1, R2 and the heat-assisted wiring trace H2 are formed in a region along the other lateral side of the support substrate 10. The heat-assisted wiring trace H2 is arranged outside of the read wiring traces R1, R2.

A magnetic head supporting portion (hereinafter referred to as a tongue) 50 is provided at the one end of the support substrate 10 by forming a U-shaped opening 40. The one ends of the write wiring traces W1, W2, the read wiring traces R1, R2 and the heat-assisted wiring traces H1, H2 respectively extend on the tongue 50. A terminal portion 21 is provided at the one end of the write wiring trace W1, and a terminal portion 22 is provided at the one end of the write wiring trace W2, on the tongue 50. Further, a terminal portion 23 is provided at the one end of the read wiring trace R1, and a terminal portion 24 is provided at the one end of the read wiring trace R2.

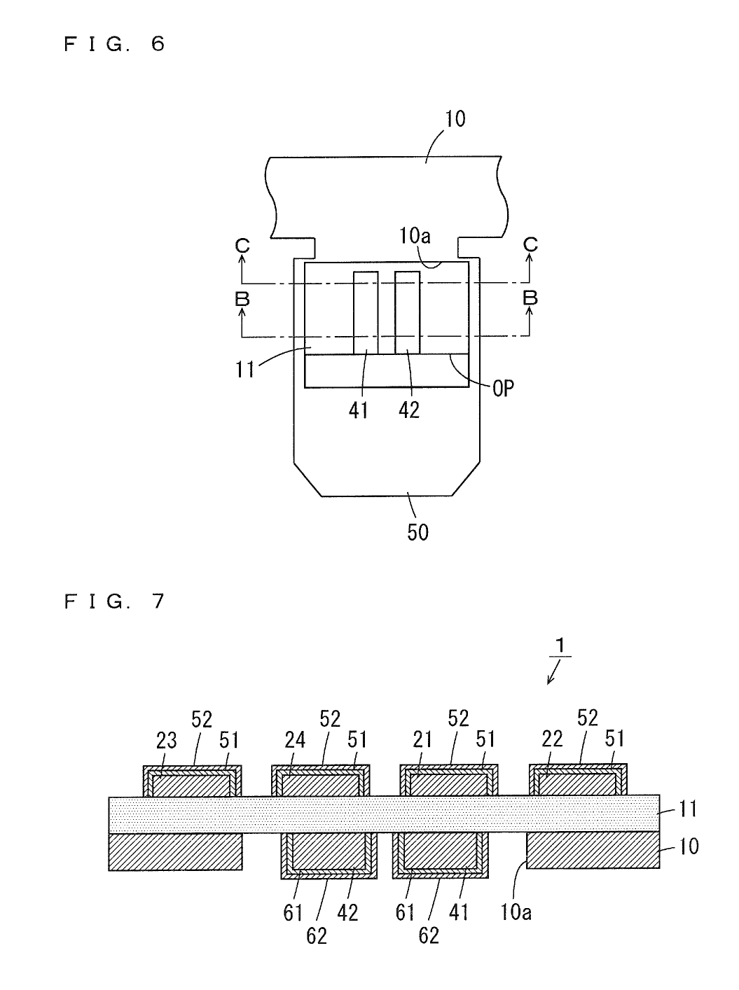

Further, a land portion L1 is provided at the one end of the heat-assisted wiring trace H1, and a land portion L2 is provided at the one end of the heat-assisted wiring trace H2, on the tongue 50. As described below, the land portions L1, L2 are respectively connected to terminal portions 41, 42 (FIG. 6) made of part of the support substrate 10.

A terminal portion 31 is provided at the other end of the write wiring trace W1, and a terminal portion 32 is provided at the other end of the write wiring trace W2, on the other end of the support substrate 10. Further, a terminal portion 33 is provided at the other end of the read wiring trace R1, and a terminal portion 34 is provided at the other end of the read wiring trace R2. Further, a terminal portion 35 is provided at the other end of the heat-assisted wiring trace H1, and a terminal portion 36 is provided at the other end of the heat-assisted wiring trace H2.

A cover insulating layer 12 made of polyimide, for example, is formed on the base insulating layer 11 to cover the write wiring traces W1, W2, the read wiring traces R1, R2 and the heat-assisted wiring traces H1, H2 except for the terminal portions 21 to 24, 31 to 36. Metal films made of nickel, for example, may be formed to respectively cover the write wiring traces W1, W2, the read wiring traces R1, R2 and the heat-assisted wiring traces H1, H2 under the cover insulating layer 12.

### (2-2) Tongue

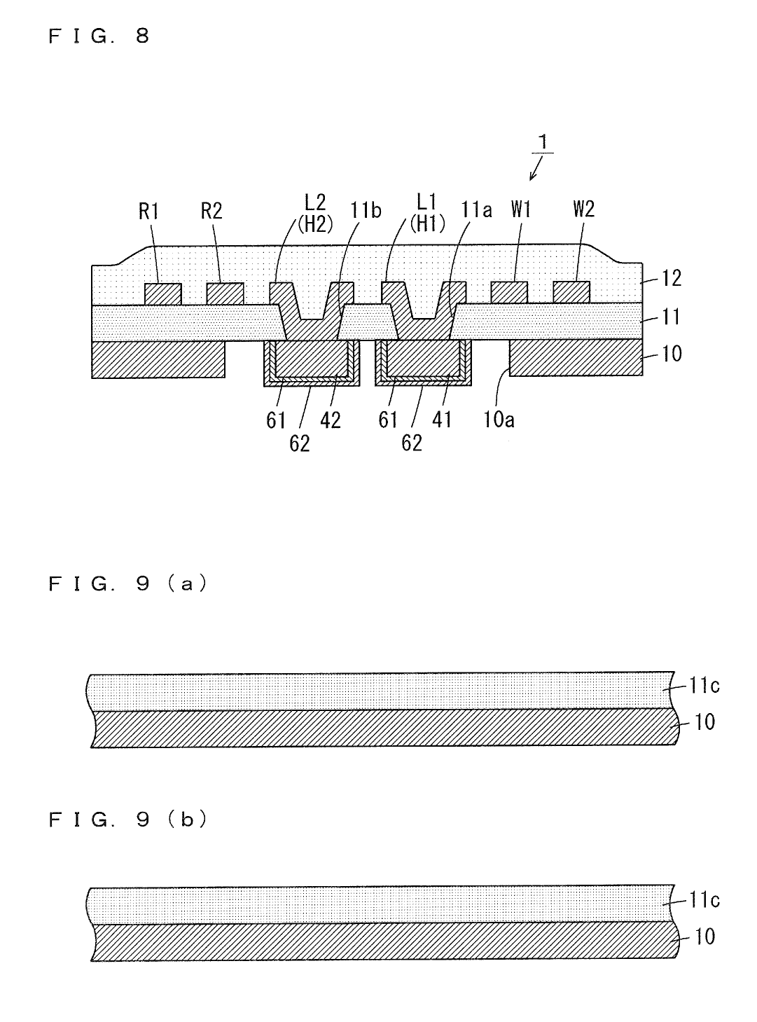

Details of the tongue 50 will be described. FIG. 5 is an enlarged plan view of the tongue 50 as viewed in one direction (the same direction as FIG. 3). FIG. 6 is an enlarged plan view of the tongue 50 as viewed in another direction (the opposite direction to FIG. 3). FIG. 7 is a cross sectional view taken along the line B-B of FIGS. 5 and 6. FIG. 8 is a cross sectional view taken along the line C-C of FIGS. 5 and 6.

As shown in FIG. 5, the terminal portions 21 to 24 of the write wiring traces W1, W2 and the read wiring traces R1, R2 are not covered by the cover insulating layer 12. On the other hand, the land portions L1, L2 of the heat-assisted wiring traces H1, H2 are covered by the cover insulating layer 12. A rectangular opening OP is formed at the base insulating layer 11. The terminal portions 21 to 24 are arranged to line along one side of the opening OP.

As shown in FIG. 6, an opening 10a is formed at the support substrate 10. The opening OP of the base insulating layer 11 overlaps with part of the opening 10a of the support substrate 10. In the opening 10a, the terminal portions 41, 42 are provided on the lower surface of the base insulating layer 11. The terminal portions 41, 42 are part of the support substrate 10, and are separated from another portion of the support substrate 10. The one end of the terminal portion 41 overlaps with the land portion L1 of FIG. 5, and the one end of the terminal portion 42 overlaps with the land portion L2 of FIG. 5. Each of the other ends of the terminal portions 41, 42 are arranged to line up along the above-mentioned one side of the opening OP of the base insulating layer 11.

As shown in FIG. 7, a plating underlayer 51 and a main plating layer 52 are sequentially formed to cover each of the side surfaces and the upper surfaces of the terminal portions 21 to 24. The plating underlayer 51 is made of nickel (Ni), for example, and the main plating layer 52 is made of gold (Au), for example.

As shown in FIG. 8, tapered holes 11a, 11b are respectively formed at portions of the base insulating layer 11 on the one end of the terminal portion 41 and the one end of the terminal portion 42. The land portion L1 is provided to come into contact with the upper surface of the base insulating layer 11, the inner peripheral surface of the hole 11a and the upper surface of the terminal portion 41. The land portion L2 is provided to come into contact with the upper surface of the base insulating layer 11, the inner peripheral surface of the hole 11b and the upper surface of the terminal portion 42.

A plating underlayer 61 and a main plating layer 62 are sequentially formed to cover each of the side surfaces and the lower surfaces of the terminal portions 41, 42. The plating underlayer 61 is made of nickel (Ni), for example, and the main plating layer 62 is made of gold (Au), for example.

A slider (not shown) that has a magnetic head is attached to the upper surface of the tongue 50. The terminal portion of the slider is electrically connected to the terminal portions 21 to 24 of the write wiring traces W1, W2, and the read wiring traces R1, R2. A heat-assisted device such as a laser diode is attached to the lower surface of the slider to project on the lower surface side of the tongue 50 through the opening OP of the base insulating layer 11 and the opening 10a of the support substrate 10. The terminal portion of the heat-assisted device is electrically connected to the terminal portions 41, 42. At the time of writing information into the magnetic disc by the magnetic head, a magnetic disc is heated by the heat-assisted device. Thus, the density of the information written into the magnetic disc can be improved.

### (2-3) Manufacturing Method

FIGS. 9 to 17 are sectional views for explaining the steps of the method of manufacturing the suspension board 1. The manufacturing step of a portion shown in FIG. 7 is shown in FIGS. 9(a), 10(a), 11(a), 12(a), 13(a), 14(a), 15(a), 16(a) and 17(a), and the manufacturing step of a portion shown in FIG. 8 is shown in FIGS. 9(b), 10(b), 11(b), 12(b), 13(b), 14(b), 15(b), 16(b) and 17(b).

First, as shown in FIGS. 9(a) and 9(b), the support substrate 10 made of a stainless steel is prepared, and the insulating layer 11c is formed on the support substrate 10 as a precursor of the base insulating layer 11. The support substrate 10 has a thickness of not less than 5 μm and not more than 50 μm, for example, and preferably has a thickness of not less than 10 μm and not more than 30 μm. As the material for the insulating layer 11c (the base insulating layer 11), a resin such as polyimide or epoxy is used.

Next, as shown in FIGS. 10(a) and 10(b), unnecessary portions of the insulating layer 11c are removed, whereby the base insulating layer 11 having a predetermined shape that has the holes 11a, 11b and the opening OP (FIGS. 5 and 6) is formed. In this case, the base insulating layer 11 may be formed of the insulating layer 11c by an exposure process or a development process, or the base insulating layer 11 may be formed of the insulating layer 11c by etching. The base insulating layer 11 has a thickness of not less than 3 μm and not more than 20 μm, for example, and preferably has a thickness of not less than 5 μm and not more than 15 μm.

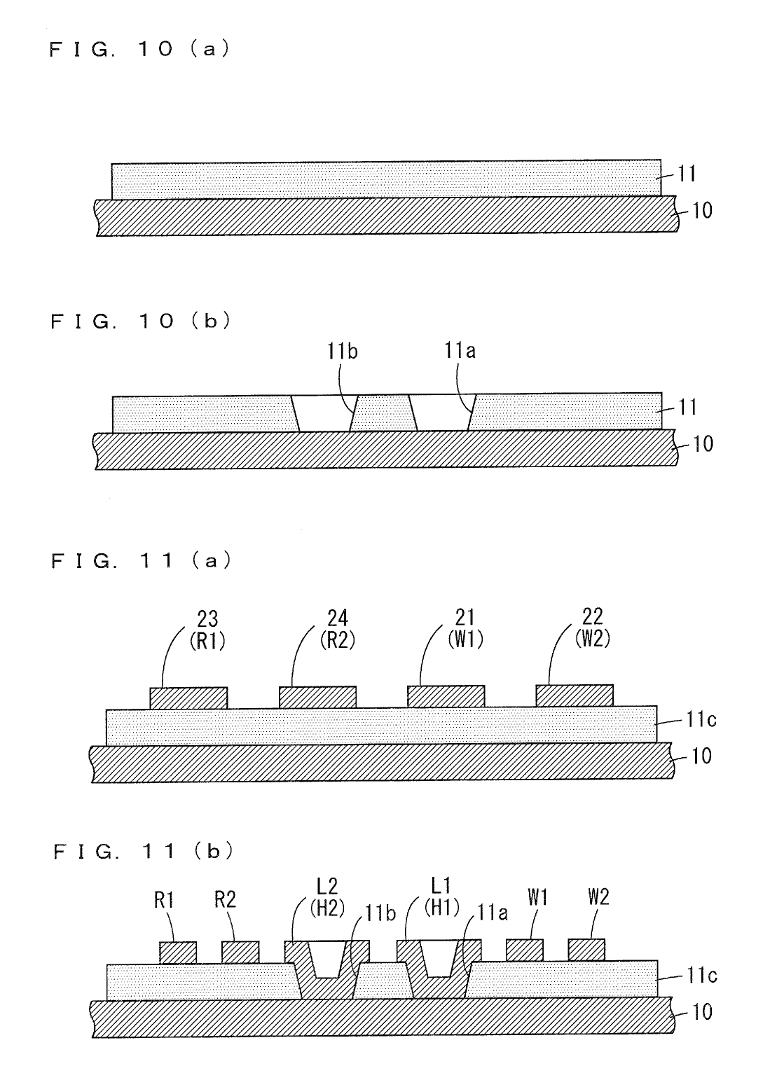

Next, as shown in FIGS. 11(a) and 11(b), the write wiring traces W1, W2, the read wiring traces R1, R2 and the heat-assisted wiring traces H1, H2 are formed on the base insulating layer 11. The land portions L1, L2 of the heat-assisted wiring traces H1, H2 are provided to come into contact with the upper surface of the base insulating layer 11, the inner peripheral surfaces of the holes 11a, 11b and the upper surface of the support substrate 10. In this case, any method out of various pattern formation methods such as a subtractive method, an additive method or a semi-additive method can be used. Further, electric plating is performed after a seed layer made of nickel and chromium, for example, is formed, whereby the write wiring traces W1, W2, the read wiring traces R1, R2 and the heat-assisted wiring traces H1, H2 may be formed.

Metal such as copper (Cu), gold (Au) or aluminum (Al), or an alloy such as a copper alloy or an aluminum alloy is used as the material for the write wiring traces W1, W2, the read wiring traces R1, R2 and the heat-assisted wiring traces H1, H2. The write wiring traces W1, W2, the read wiring traces R1, R2 and the heat-assisted wiring traces H1, H2 have a thickness of not less than 3 μm and not more than 16 μm, for example, and preferably has a thickness of not less than 6 μm and not more than 13 μm.

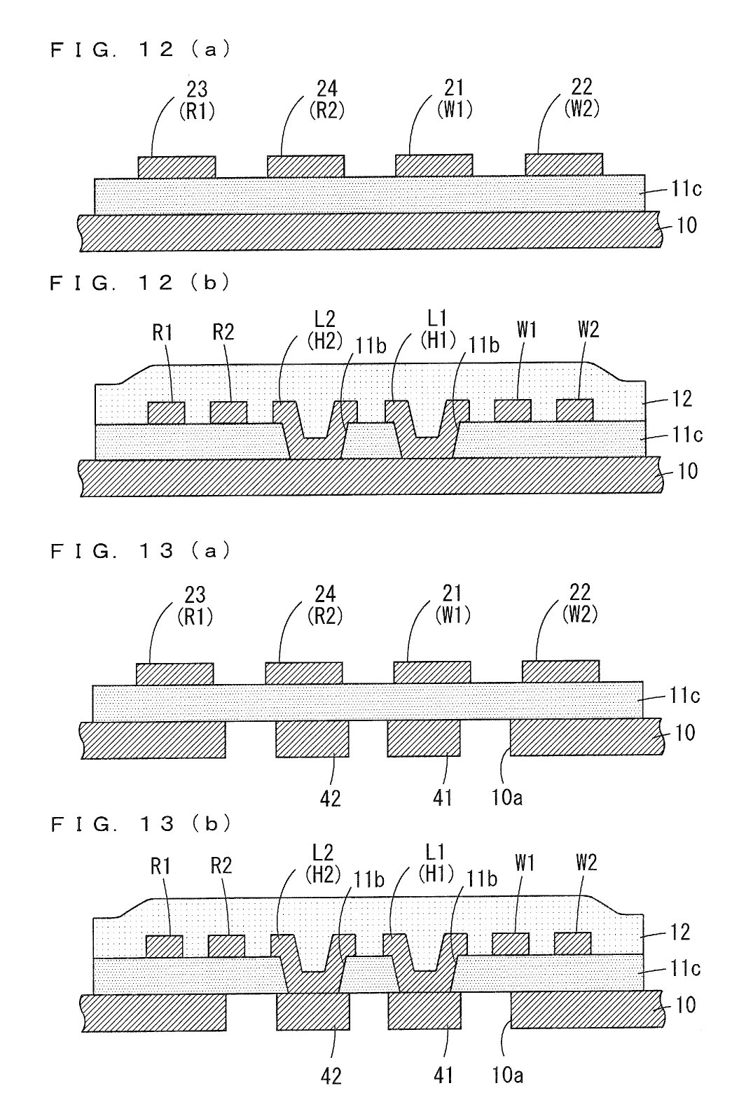

Next, as shown in FIGS. 12(a) and 12(b), the cover insulating layer 12 is formed on the base insulating layer 11 to cover the write wiring traces W1, W2, the read wiring traces R1, R2 and the heat-assisted wiring traces H1, H2 except for the terminal portions 21 to 24 and the terminal portions 31 to 36 (FIG. 3). Specifically, an insulating layer as a precursor of the cover insulating layer 11 is first formed at least on the base insulating layer 11 to cover the entire write wiring traces W1, W2, the read wiring traces R1, R2 and the heat-assisted wiring traces H1, H2. Thereafter, unnecessary portions of the insulating layer are removed such that the terminal portions 21 to 24, 31 to 36 are exposed, whereby the cover insulating layer 12 having a predetermined shape is formed. Similarly to the formation of the base insulating layer 11, the cover insulating layer 12 may be formed by the exposure process and the development process, or the cover insulating layer 12 may be formed by etching.

For example, a resin such as polyimide or epoxy is used as the material for the cover insulating layer 12. The cover insulating layer 12 has a thickness of not less than 5 μm and not more than 30 μm, for example, and preferably has a thickness of not less than 10 μm and not more than 20 μm.

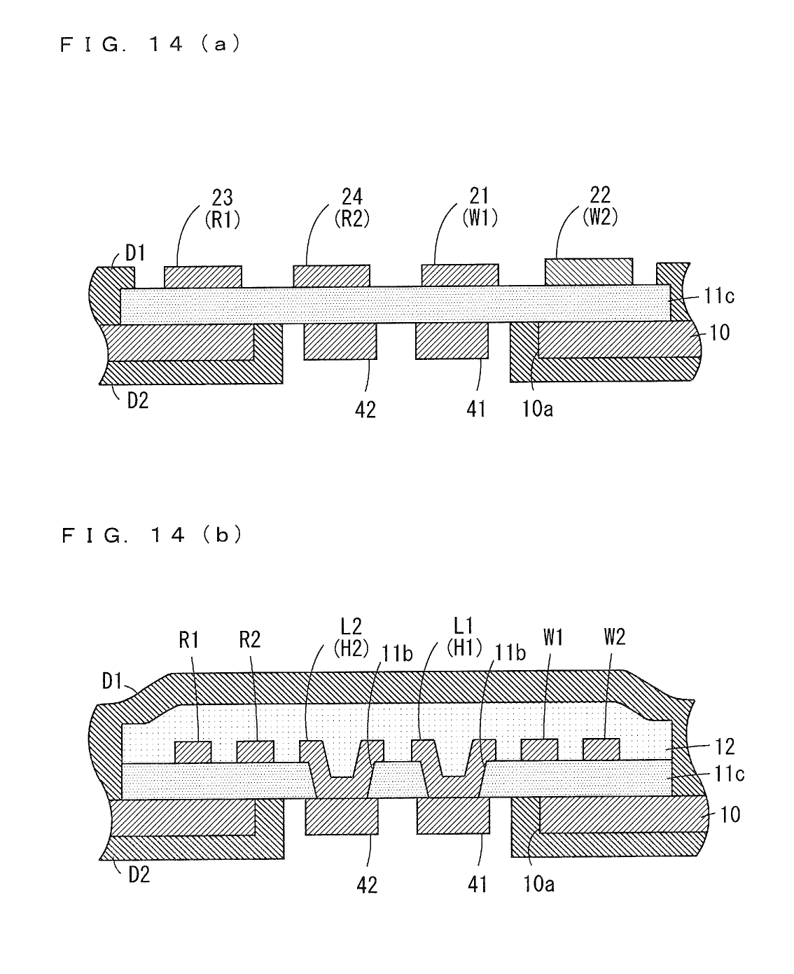

Then, as shown in FIGS. 13(a) and 13(b), part of the support substrate 10 is removed by etching. Thus, the opening 10a is formed at the support substrate 10, and the terminal portions 41, 42 made of portions of the support substrate 10 that come into contact with the land portions L1, L2 are separated from other portions of the support substrate 10.

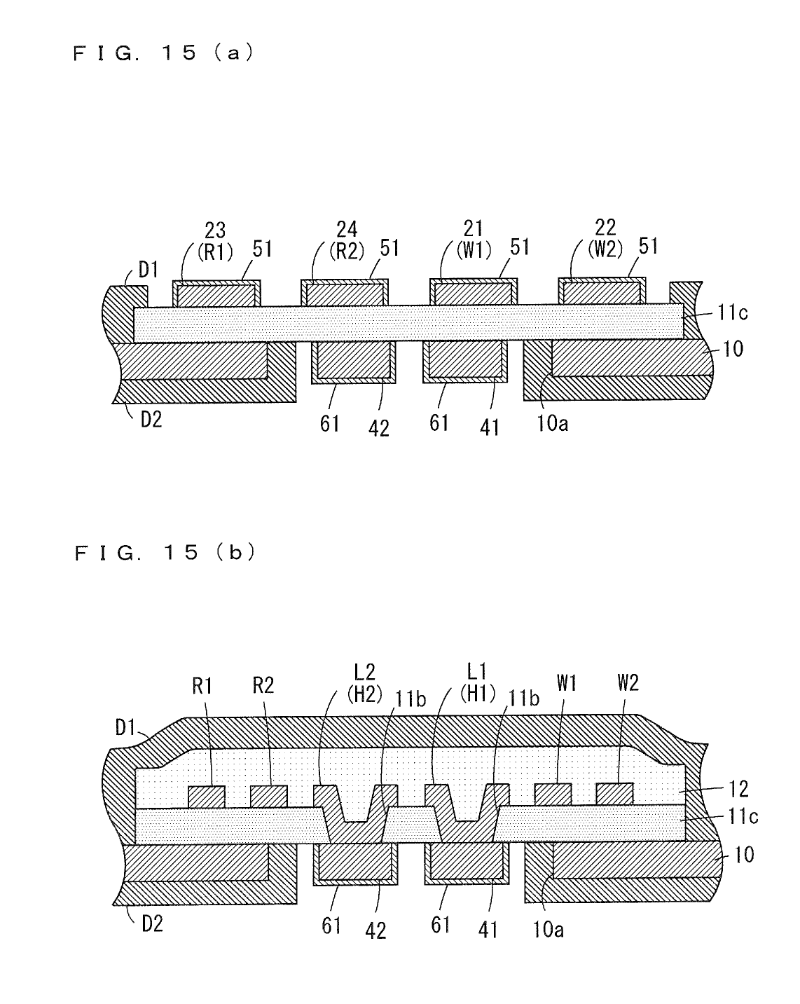

Next, as shown in FIGS. 14(a) and 14(b), a plating resist layer D1 is formed on at least the exposed upper surface of the support substrate 10 on the upper surface side of the support substrate 10. In the examples of FIGS. 14(a) and 14(b), the plating resist layer D1 is formed on the exposed upper surfaces of the support substrate 10, the base insulating layer 11 and the cover insulating layer 12 except for the terminal portions 21 to 24 and the terminal portions 31 to 36 (FIG. 3). Further, a plating resist layer D2 is formed to cover the lower surfaces of the support substrate 10 except for the terminal portions 41, 42 and the side surface of the opening 10a on the lower surface side of the support substrate 10. The plating resist layers D1, D2 are formed by performing exposure and development of a dry film resist, for example.

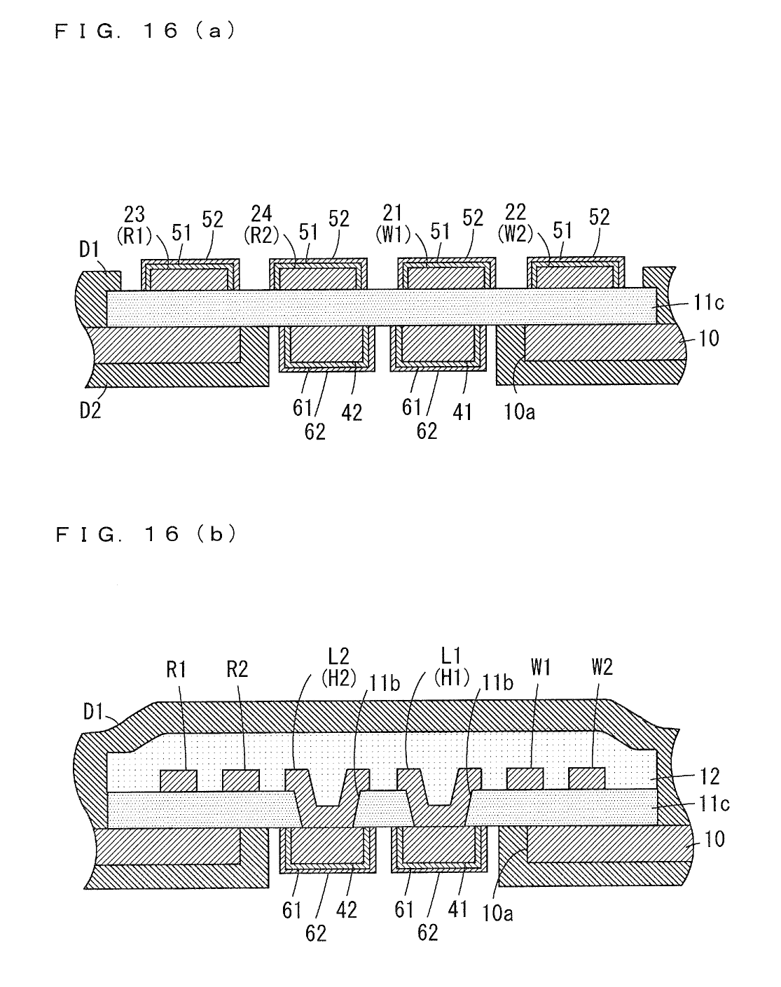

Next, as shown in FIGS. 15(a) and 15(b), the plating underlayers 51 are formed to cover the terminal portions 21 to 24, and the plating underlayers 61 are formed to cover the terminal portions 41, 42. Specifically, the plating underlayers 51, 61 are formed using the plating apparatus 100a of FIG. 2. In this case, the support substrate 10 corresponds to the stainless steel plate 150 of FIG. 2, and the terminal portions 41, 42 correspond to the portion to be plated. The plating underlayers 61 are formed on the terminal portions 41, 42 by the electrolytic plating process after the passive films at the surfaces of the terminal portions 41, 42 are removed by the reverse electrolytic process. Further, the write wiring traces W1, W2, the read wiring traces R1, R2 and the heat-assisted wiring traces H1, H2 correspond to the conductor layer 152 of FIG. 2, and the terminal portions 21 to 24, 31 to 36 correspond to the portion to be plated. The plating underlayers 51 are formed on the terminal portions 21 to 24, 31 to 36 by the electrolytic plating process without the reverse electrolytic process.

The plating apparatus 100 of FIG. 1 may be used instead of the plating apparatus 100a of FIG. 2. In this case, the plating underlayers 61 are formed on the terminal portions 41, 42 in the plating apparatus 100 of FIG. 1, and the plating underplayers 51 are formed on the terminal portions 21 to 24, 31 to 36 in another plating apparatus.

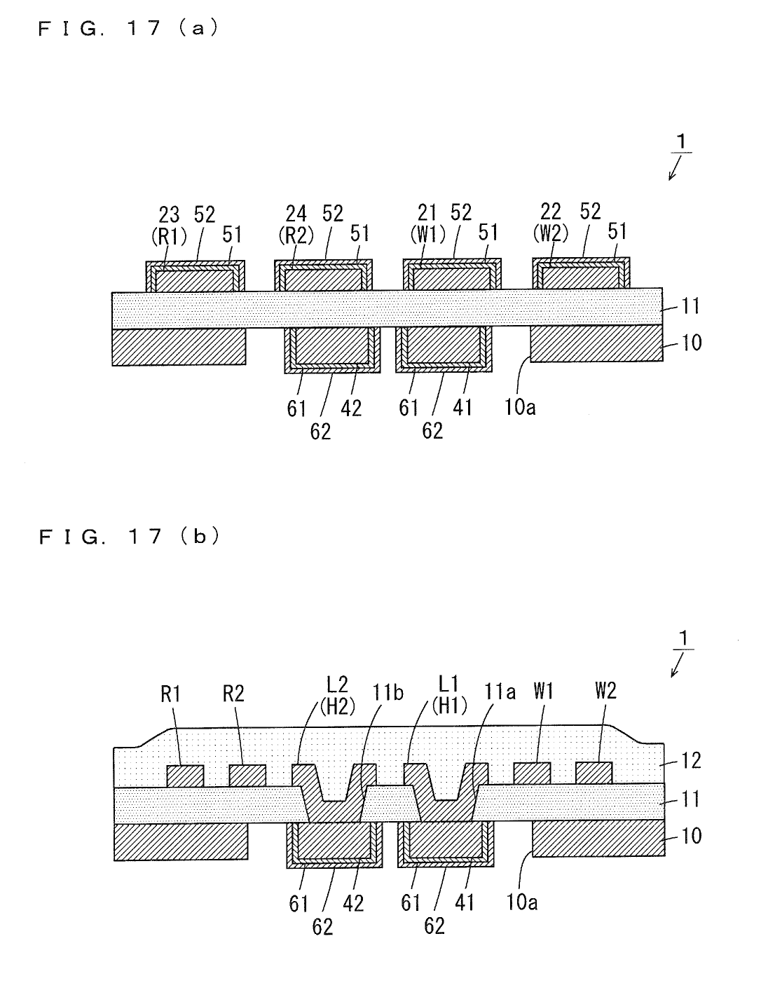

Next, as shown in FIGS. 16(a) and 16(b), the main plating layers 52 are formed on the plating underlayers 51 by electroplating, and the main plating players 62 are formed on the plating underlayers 61.

Thereafter, as shown in FIGS. 17(a) and 17(b), the plating resist layers D1, D2 are removed, and unnecessary portions of the support substrate 10 are further removed by etching, whereby the suspension board 1 is completed.

### (2-4) Effects

In the present embodiment, the plating underlayers 61 of the suspension board 1 are formed using the plating apparatus 100 of FIG. 1 or the plating apparatus 100a of FIG. 2. Thus, the plating underlayers 61 having high adhesion can be formed while corrosion of the support substrate 10, the write wiring traces W1, W2, the read wiring traces R1, R2 and the heat-assisted wiring traces H1, H2 is prevented.

Further, when the plating apparatus 100a of FIG. 2 is used, the plating underlayers 51, 61 can be simultaneously formed. Thus, the efficiency of the manufacturing step of the suspension board 1 can be increased.

### (3) Other Embodiments

While the above-mentioned embodiment is an example in which the plating method according to the present invention is used for manufacturing the suspension board 1 used for an actuator in a hard disc drive, the plating method according to the present invention may be used for manufacturing another electronic product, a circuit board or the like.

### (4) Correspondences between Constituent Elements in Claims and Parts in Preferred Embodiments

In the following paragraphs, non-limiting examples of correspondences between various elements recited in the claims below and those described above with respect to various preferred embodiments of the present invention are explained.

In the present embodiment, the plating apparatuses 100, 100a are examples of a plating apparatus, the stainless steel plate 150, the conductor layer 152, the support substrate 10, the write wiring traces W1, W2, the read wiring traces R1, R2 and the heat-assisted wiring traces H1, H2 are examples of a member to be plated, the plating tank 101 is an example of a plating tank, the electrode 104 is an example of a first electrode, the electrode 105 is an example of a second electrode, the rectifier 110 is an example of a first voltage applier, the rectifier 111 is an example of a second voltage applier, the plating underlayers 51, 61 are examples of a plating layer, the first region RG1 is an example of a first region, the second region RG2 is an example of a second region, the transport roller 210 is an example of a transporter, the electrode 107 is an example of a third electrode, the rectifier 112 is an example of a third voltage applier, the stainless steel plate 150 and the support substrate 10 are examples of a first member, the conductor layer 152, the write wiring traces W1, W2, the read wiring traces R1, R2 and the heat-assisted wiring traces H1, H2 are example of a second member.

Further, the suspension board 1 is an example of a printed circuit board, the support substrate 10 is an example of a support substrate, the base insulating layer 11 is an example of a base insulating layer, the heat-assisted wiring traces H1, H2 are examples of a first wiring trace, the terminal portions 41, 42 are examples of a first terminal portion, the write wiring traces W1, W2 and the read wiring traces R1, R2 are examples of a second wiring trace and the terminal portions 21 to 24 are examples of a second terminal portion.

As each of various elements recited in the claims, various other elements having configurations or functions described in the claims can be also used.

While preferred embodiments of the present invention have been described above, it is to be understood that variations and modifications will be apparent to those skilled in the art without departing the scope and spirit of the present invention. The scope of the present invention, therefore, is to be determined solely by the following claims.

### INDUSTRIAL APPLICABILITY

The present invention can be effectively utilized for various electronic components and printed circuit boards.

1. A plating apparatus for forming a plating layer at a surface of a member to be plated that includes a stainless steel, comprising:
a plating tank that stores an electrolytic solution;
a first electrode provided in the plating tank;
a second electrode provided in the plating tank;
a first voltage applier that applies a voltage between the member to be plated and the first electrode such that the member to be plated is an anode; and
a second voltage applier that applies a voltage between the member to be plated and the second electrode such that the member to be plated is a cathode, wherein
the plating layer is formed at a predetermined portion to be plated by application of a voltage by the second voltage applier after a passive film is removed from the portion to be plated of the member to be plated by application of a voltage by the first voltage applier.

2. The plating apparatus according to claim 1, wherein
the first and second electrodes are integrated or separated, and the first and second voltage appliers are integrated or separated.

3. The plating apparatus according to claim 1, wherein
the first and second electrodes are separated,
the first electrode is arranged in a first region in the plating tank,
the second electrode is arranged in a second region in the plating tank, and
the plating apparatus further comprising a transporter that transports the member to be plated such that the member to be plated sequentially pass through first and second regions in the plating tank.

4. The plating apparatus according to claim 1, wherein
the electrolytic solution stored in the plating tank includes a sulfuric acid chemical solution, and a pH of the electrolytic solution is less than 2.0.

5. The plating apparatus according to claim 1, further comprising:
a third electrode provided in the plating tank; and
a third voltage applier that applies a voltage between the member to be plated and the third electrode such that the member to be plated is a cathode, wherein
the member to be plated has a first member made of a stainless steel and a second member made of a conductive material other than a stainless steel, and the portion to be plated is provided at each of the first and second members, and
the first and second electrodes are arranged to be opposite to the first member of the member to be plated, and the third electrode is arranged to be opposite to the second member of the member to be plated.

6. A plating method for forming a plating layer at a surface of a member to be plated that includes a stainless steel, including the steps of:
removing a passive film from a predetermined portion to be plated of the member to be plated by applying a voltage between the member to be plated and an electrode in a plating tank that stores an electrolytic solution such that the member to be plated is an anode; and
forming the plating layer at the portion to be plated of the member to be plated by applying a voltage between the member to be plated and an electrode in the plating tank such that the member to be plated is a cathode.

7. The plating method according to claim 6, wherein
the member to be plated has a first member made of a stainless steel and a second member made of a conductive material other than a stainless steel, and the portion to be plated is provided at each of the first and second members,
the step of removing the passive film includes the step of removing the passive film from the portion to be plated of the first member of the member to be plated, and
the step of forming the plating layer includes
the step of forming the plating layer at a portion to be plated of the first member of the member to be plated, and
the step of forming the plating layer at a portion to be plated of the second member of the member to be plated.

8. The plating method according to claim 7, wherein
the step of forming the plating layer includes the step of forming the plating layer at the portion to be plated of the second member of the member to be plated while forming the plating layer at the portion to be plated of the first member of the member to be plated.

9. A method of manufacturing a printed circuit board including the steps of:
forming a base insulating layer on a support substrate made of a stainless steel as a member to be plated;
forming a first wiring trace on the base insulating layer to be electrically connected to one portion of the support substrate;
forming a first terminal portion as a portion to be plated made of the one portion by removing a surrounding portion of the one portion of the support substrate such that the one portion of the support substrate is separated from a remaining portion, and
forming a plating layer at the first terminal portion of the support substrate by the plating method according to claim 6.

10. The method of manufacturing the printed circuit board according to claim 9 that further includes the step of forming a second wiring trace as the member to be plated on the base insulating layer, wherein
the support substrate constitutes the first member of the member to be plated, and the second wiring trace constitutes the second member of the member to be plated,
the second wiring trace includes a second terminal portion as the portion to be plated, and
the step of forming the plating layer includes the step of forming the plating layer at the first terminal portion of the support substrate and the second terminal portion of the second wiring trace by a plating method wherein
the member to be plated has a first member made of a stainless steel and a second member made of a conductive material other than a stainless steel, and the portion to be plated is provided at each of the first and second members,
the step of removing the passive film includes the step of removing the passive film from the portion to be plated of the first member of the member to be plated, and
the step of forming the plating layer includes
the step of forming the plating layer at a portion to be plated of the first member of the member to be plated, and
the step of forming the plating layer at a portion to be plated of the second member of the member to be plated.

11. A printed circuit board manufactured by the method according to claim 9.
